(19) United States
(12) Patent Application Publication
(10) Pub. No.: US 2026/0215062 A1
(43) Pub. Date: Jul. 23, 2026

(54) OPTICAL LAYER FOR PIXELS OF MICRO-LIGHT EMITTING DIODE (LED) DEVICES

(71) Applicant: Lumileds LLC, San Jose, CA (US)

(72) Inventors: Xavier Garcia Santiago, Karlsruhe (DE); Toni Lopez, Vaals (NL); Joseph Flemish, Palo Alto, CA (US)

(73) Assignee: Lumileds LLC, San Jose, CA (US)

(21) Appl. No.: 19/137,947

(22) PCT Filed: Nov. 27, 2023
(86) PCT No.: PCT/US2023/081071

§ 371 Date: Jun. 11, 2025

Related U.S. Application Data
(60) Provisional application No. 63/387,336, filed on Dec. 14, 2022.

(51) Int. Cl. H10H 29/856; H10H 29/01; H10H 29/80

(52) U.S. Cl. CPC H10H 29/856; H10H 29/034; H10H 29/8421

(57) ABSTRACT

A micro-light emitting diode (uLED) comprises: a pixel defined by a mesa of semiconductor layers having a sidewall, the mesa including an n-type layer, an active region, and a p-type layer; a first dielectric material surrounding the sidewall of the pixel; a current spreading layer in contact with one or more n-contact materials and the n-type layer; an optical layer disposed on the current spreading layer, the optical layer comprising: an optical segment opposite the n-type layer and the first dielectric material, the optical segment comprising a second dielectric material, and a reflective sidewall adjacent to the optical segment and opposite portions of the one or more n-contact materials; and an anode in contact with the p-type layer. MicroLED dies and devices comprising the uLEDs and method of making the same are also provided.

### TECHNICAL FIELD

Embodiments of the disclosure generally relate to micro-light emitting diodes (uLEDs), dies, and devices with the same, and methods of manufacturing and using the same. A uLED comprises a pixel and an optical layer or coating above an emitting surface of the pixel, preferably on a current spreading layer. MicroLED dies include a plurality of pixels and an optical layer or coating above emitting surfaces of the pixels, preferably on a current spreading layer. MicroLED devices include the uLED dies, which suitable for hybrid-bonding with target wafers, for example, CMOS wafers, in that there is a combination of a metal-to-metal bonds and dielectric-to-dielectric bonds between the uLED die, which may be referred to as a source wafer, and the target wafer.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region.

Various emerging display applications, including wearable devices, head-mounted, and large-area displays require miniaturized chips composed of arrays of microLEDs (uLEDs or uLEDs) with a high density having a lateral dimension down to less than 100 μm ×100 μm. MicroLEDs (uLEDs) typically have dimensions of about 50 μm in diameter or width and smaller that are used to in the manufacture of color displays by aligning in close proximity microLEDs comprising red, blue and green wavelengths.

Monolithic uLED arrays may require metal (e.g., Al-or Ag-based) side-contacts. These contacts may serve as the electrical cathode for each pixel and also provide reflective sidewalls in between the pixels to reduce light scattering and propagation in lateral directions. With some monolithic uLED architectures, a substrate, sometimes referred to as a “growth” substrate (e.g., sapphire, silicon), may be removed after an array is integrated with a backplane driver and controller combination. This offers multiple advantages such as enhanced light extraction and beam profiling. One typical approach to remove a substrate, for example a sapphire substrate, is by a laser lift-off (LLO) process where a laser beam (UV laser in the case of sapphire substrate) is used to detach the substrate from the epitaxial layers (which were grown on the substrate). With such architectures, it can be a challenge to achieve excellent brightness performance,

There is a need for improving and/or maximizing optical efficiency in designs of uLEDs.

### SUMMARY

Provided herein are micro-light emitting diodes (uLEDs), dies, and devices with the same, and methods of manufacturing and using the same.

An aspect provides a micro-light emitting diode (uLED) comprising: a pixel defined by a mesa of semiconductor layers having a sidewall, the mesa including an n-type layer, an active region, and a p-type layer; a first dielectric material surrounding the sidewall of the pixel; a current spreading layer in contact with one or more n-contact materials and the n-type layer; an optical layer disposed on the current spreading layer, the optical layer comprising: an optical segment opposite the n-type layer and the first dielectric material, the optical segment comprising a second dielectric material, and a reflective sidewall adjacent to the optical segment and opposite portions of the one or more n-contact materials; and an anode in contact with the p-type layer. In one or more embodiments, the optical layer is present in a configuration that is effective as a lens for projected light of the pixel and/or an anti-reflective coating.

In another aspect, a micro-light emitting diode (uLED) die comprises: a plurality of pixels each having a sidewall and being defined by a mesa of semiconductor layers, each the mesas including an n-type layer, an active region, and a p-type layer; a first dielectric material surrounding the sidewall of each of the pixels; a plurality of n-contact materials between adjacent pixels on the first dielectric material; a current spreading layer in contact with a common cathode each of the n-type layers, and the n-contact materials; an optical layer on the current spreading layer, the optical layer comprising: an optical segment opposite each of the n-type layers and the first dielectric material, the optical segment comprising a second dielectric material, and a reflective sidewall adjacent to the optical segment and opposite portions of the n-contact materials; and a plurality of anodes in contact with each of the p-type layers. In one or more embodiments, the optical layer is present in a configuration that is effective as a lens for projected light of each of the pixels and/or an anti-reflective coating.

An aspect provides a method of manufacturing a micro-light emitting diode (uLED) device comprising: depositing a coating material on a micro-light emitting diode (uLED) die comprising: a plurality of pixels that comprises a mesa of semiconductor layers, a first dielectric material surrounding a sidewall of each of the pixels, and a current spreading layer connecting a common cathode and each n-type layer of the mesas; selectively etching the coating material to prepare optical segments on the current spreading layer opposite each of the n-type layers and the first dielectric material the optical segments comprising a second dielectric material; and depositing and etching a metal material to prepare reflective sidewalls of the optical segments to form an optical layer comprising the optical segments and the reflective sidewalls. In one or more embodiments, the optical layer is present in a configuration that is effective as a lens for projected light of each of the pixels and/or an anti-reflective coating.

Further aspects are micro-light emitting diode (uLED) devices, each comprising: a source wafer comprising any the micro-light emitting diode (uLED) die herein comprising any uLED herein; and a target wafer bonded to the source wafer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating in cross-section a micro-light emitting diode (uLED) according to one or more embodiments;

FIG. 2 is a schematic view illustrating in cross-section a micro-light emitting diode (uLED) device including s of FIG. 1 according to one or more embodiments;

FIG. 3 is a schematic view illustrating in cross-section a micro-light emitting diode (uLED) according to one or more embodiments;

FIG. 4 is a schematic view illustrating in cross-section a micro-light emitting diode (uLED) device including uLEDs of FIG. 3 according to one or more embodiments;

FIG. 5 is a schematic view illustrating in cross-section a micro-light emitting diode (uLED) according to one or more embodiments;

FIG. 6 is a schematic view illustrating in cross-section a micro-light emitting diode (uLED) device including uLEDs of FIG. 5 according to one or more embodiments;

FIG. 7 is a schematic view illustrating in cross-section a micro-light emitting diode (uLED) according to one or more embodiments;

FIG. 8 is a schematic view illustrating in cross-section a micro-light emitting diode (uLED) device including uLEDs of FIG. 75 according to one or more embodiments;

FIG. 9 provides a process flow diagram for manufacture of a micro-light emitting diode (uLED) die according to one or more embodiments;

FIG. 10 provides a process flow diagram for manufacture of a micro-light emitting diode (uLED) die according to one or more embodiments;

FIG. 11 illustrates a top plan view of an exemplary display device according to one or more embodiments;

FIG. 12 schematically illustrates an exemplary display system comprising uLED devices according to embodiments herein; and

FIG. 13 shows a block diagram of a visualization system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of ±1-5%. In a preferred embodiment, one or more dimensions of height, width, depth, thickness have values of 200 micrometers ±1-5%. In some instances, the LEDs are referred to as micro-LEDs (uLEDs or uLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometers to 300 micrometers, and all values and sub-ranges therebetween.

LEDs capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

Methods of depositing materials, layers, and thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type layer, active region, and p-type layer are formed according to methods known in the art. In one or more embodiments, the semiconductor layers are formed by epitaxial (EPI) growth. The semiconductor layers according to one or more embodiments comprise epitaxial layers, III-nitride layers, or epitaxial III-nitride layers. In one or more embodiments, the semiconductor layers comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AIN), indium nitride (InN), aluminum gallium nitride (AlGaN), indium gallium nitride (InGaN), indium aluminum nitride (InAIN), aluminum indium gallium nitride (AlInGaN) and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate, or on a substrate with one or more films or features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AIN, InN and alloys), metal alloys, and other conductive materials, metal phosphides (e.g., InP) depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed are also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Suitable applications for uLED devices herein include but are not limited to augmented reality/virtual reality (AR/VR) systems. One or more AR/VR systems include: augmented (AR) or virtual reality (VR) headsets, glasses, or projectors.

In some uLED architectures, a common top cathode contact is arranged with a thin current spreading layer (e.g., a transparent conducting oxide TCO layer). Exemplary current spreading layers comprise indium tin oxide (ITO) and/or indium zinc oxide (IZO). The semiconductor layers may be thinned down into 1-2 micron range, which enables a good ohmic contact formation to the TCO layer. Bottom anode contacts for each pixel electrically access a target wafer such as a CMOS. Such architectures have problems concerning brightness performance, which can be limited by: (1) absorbing layers (e.g., p-metal and metal-side walls impacting extraction efficiency (ExE)), (2) lack of scattering (low ExE), and (3) broad angular radiation (e.g., Lambertian).

Advantageously, uLEDS and dies and devices including the same herein address such problems by introducing an optical coating or layer on an emitting surface of pixels and of monolithic pixel arrays or dies. The optical coating or layer is designed to achieve emission directionality while maximizing light extraction efficiency (ExE) and internal quantum efficiency (IQE). In one or more embodiments, the optical layer may be effective as a lens for projected light of the pixel and/or as an anti-reflective coating. An optical layer comprises an optical segment and a reflective sidewall. In one or more embodiments, the optical coating (without a reflective sidewall), is effective as an anti-reflective coating. The optical coating and/or optical segments are typically a dielectric material such as silicon dioxide (SiO₂) or silicone. The optical coating and/or segments may be multilayered. Reflective sidewalls are a metal, for example, alumina, and extend any reflective walls of the pixel underneath. The optical coating may be patterned to prepare optical segments. The optical segments may be patterned to accommodate end use applications. In one or more embodiments, a periodic pattern design of the optical segments has concave lens shape of similar size as the pixel area. Both periodic pattern and pixel array are aligned. It induces light beaming preferentially directed on axis. Compared to a reference design, simulations show large enhancement levels greater than 90% flux gain within a collection angle cone of 60 deg. Compared to a uLED without an optical layer otherwise having a same structure, upon application of power a far-field angular emission response for an angle (0) of greater than or equal to 0° to less than or equal to 40° is higher of a pixel of a uLED having a planar optical segment and a reflective sidewall according to embodiments herein.

In one or more embodiments, optical layers, optical segments, and/or optical coatings herein have a minimal thickness in a range of 500 nanometers to 1 micrometer, and all values and subranges therebetween. In one or more embodiments, the optical segments are centered on the pixel. In some embodiments, the optical segment or coating comprises a layered structure. In one or more embodiments, the optical segment or coating comprises a thin layer stack to form an interferometric filter, including, for example, layered pairs of high/low refractive index films that are arranged with thicknesses around lambda/4, where lambda is the wavelength of light in the medium it propagates through. In one or more embodiments, pairs of films comprise silicon dioxide (SiO₂) and titanium dioxide (TiO₂) layers. In one or more embodiments, pairs of films comprise silicon dioxide (SiO₂) and niobium pentoxide (NbO₅) layers.

MicroLEDS and dies herein primarily aim at preferentially generating light with a narrow angular distribution on-axis centered. This can be effectively arranged by fabricating a transparent thin optical segment or coating above the pixels. Inclusion of reflective sidewalls surrounding the optical segments facilitates the elimination of cross-talk and maximizes brightness.

In one or more embodiments, optical layers and coatings herein are effective to affect projected light from the light emitting array. In one or more embodiments, optical layers and coatings herein are effective as anti-reflective coatings. In one or more embodiments, optical layers and coatings herein are effective for beaming. In some embodiments, the optic layers and/or coatings can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

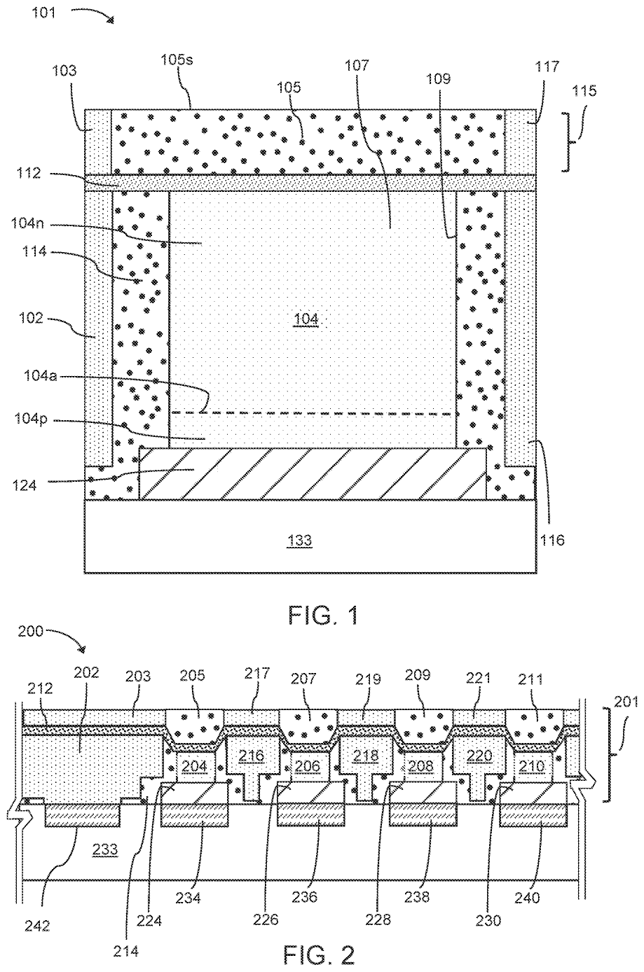

FIG. 1 is a schematic view illustrating in cross-section a micro-light emitting diode (uLED) according to one or more embodiments. The uLED 101 includes a pixel 107 defined by a mesa 104 of semiconductor layers having a sidewall 109, the mesa including an n-type layer 104n, an active region 104a, and a p-type layer 104p. A first dielectric material 114 surrounds the sidewall 109 of the pixel 107. A current spreading layer 112 is in contact with an n-contact material 116, the n-type layer 104n, a portion of the first dielectric material 114, and a common cathode 102. The n-contact material 116 and the common cathode 102 are in electrical contact with the n-type layer 104n by way of the current spreading layer 112. An anode 124 is in contact with the p-type layer 104p, and is positioned on a substrate 133.

An optical layer 115 is disposed on the current spreading layer 112, the optical layer 115 comprises: an optical segment 105 and a reflective sidewall 117 adjacent to the optical segment 105. The optical segment 105 is opposite the n-type layer 104n and the first dielectric material 114. In one or more embodiments, the optical segment 105 comprises a second dielectric material. The reflective sidewall 117 is opposite portions of the n-contact material 116 and the common cathode 105. In one or more embodiments, the optical layer 115 is present in a configuration that is effective as a lens for projected light of the pixel and/or an anti-reflective coating. In this embodiment, the optical segment 105 comprises a planar surface 105s opposite the current spreading layer 112. Reference to a planar surface herein means that such surface is substantially in the same plane, with any variation from the plane being less than or equal to about 0.5% or 0.25% of the optical segment thickness. A minimal thickness of an optical segment with a planar surface is based on an average thickness of the entire optical segment.

FIG. 2 is a schematic view illustrating in cross-section a micro-light emitting diode (uLED) device including a die with uLEDs of FIG. 1 according to one or more embodiments. The uLED device 200 includes a uLED die 201 comprising a plurality of pixels each having a sidewall (analogously to FIG. 1) and each defined by a mesa 204, 206, 208, 210 of semiconductor layers, each the mesas 204, 206, 208, 210 including an n-type layer, an active region, and a p-type layer. A first dielectric material 214 surrounds the sidewall of each of the pixels. A plurality of n-contact materials 216, 218, 220 is positioned between adjacent pixels on the first dielectric material 214. A common electrode 202 is in electrical contact with the n-type layers and the n-contact materials 216, 218, 220. A plurality of anodes 224, 226, 228, 230, namely die anodes, are in contact with each of the p-type layers and corresponding contacts or electrodes (anodes) 234, 236, 238, 240 of a substrate 233. The common cathode 202 is in contact with corresponding contact or electrode (cathode) 242 of the substrate 233. In FIG. 2, upper edges of the mesas 204, 206, 208, 210 are off-set from upper edges of the n-contact materials 216, 218, 220 and common cathode 202. It is understood that other designs may planarize a combination of the upper edges of the mesas 204, 206, 208, 210 and the n-contact materials 216, 218, 220 and common cathode 202.

An optical layer comprising: optical segments 205, 207, 209, and 211, and reflective sidewalls 203, 217, 219, 211 adjacent to the optical segments 105 is disposed on the current spreading layer 212. The optical segments 205, 207, 209, and 211 are opposite the n-type layers of the mesas 204, 206, 208, and 210 and portions of the first dielectric material 214. In one or more embodiments, the optical segments 205, 207, 209, and 211 comprise a second dielectric material. The reflective sidewalls 217, 219, 211 are opposite portions of the n-contact materials 216, 218, and 220. The reflective sidewall 203 is opposite the common cathode 202. In one or more embodiments, the optical layer is present in a configuration that is effective as a lens for projected light of the pixel and/or an anti-reflective coating. In this embodiment, the optical segments 205, 207, 209, and 211 comprise a planar surface opposite the current spreading layer 212 The substrate 233 in one or more embodiments, is a target wafer to which die 201, as a source wafer, is bonded, for example, hybrid-bonded. In one or more embodiments, the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

According to one or more embodiments, for assembly of the uLED device, a process to achieve hybrid bonding is conducted. That is, the die 201 is hybrid-bonded to the substrate 233, which may be a target substrate having target metal contacts or electrodes. By way of example, a surface of each of the anodes 224, 226, 228, 230 is bonded to a surface of each corresponding contacts or electrodes (anodes) 234, 236, 238, 240 of the substrate 233. The common cathode 202 is bonded to contact or electrode (cathode) 242 of the substrate 233. In addition, first dielectric material 214 bonds to a body of the substrate 233, which in one or more embodiments, is a dielectric material.

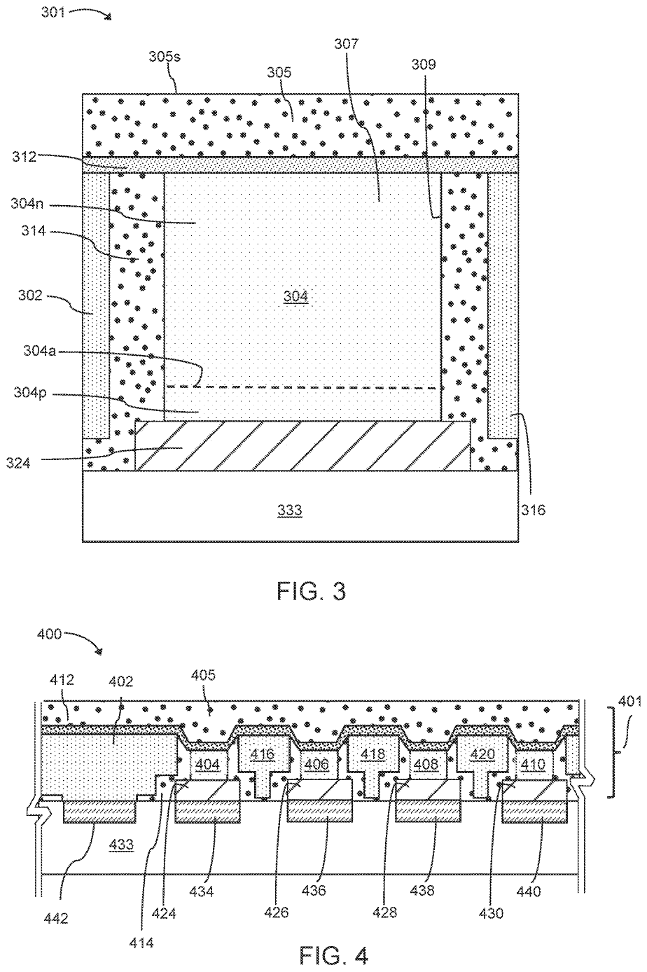

FIG. 3 is a schematic view illustrating in cross-section a micro-light emitting diode (uLED) according to one or more embodiments. The uLED 301 includes a pixel 307 defined by a mesa 304 of semiconductor layers having a sidewall 309, the mesa including an n-type layer 304n, an active region 304a, and a p-type layer 304p. A first dielectric material 314 surrounds the sidewall 309 of the pixel 307. A current spreading layer 312 is in contact with an n-contact material 316, the n-type layer 304n, a portion of the first dielectric material 314, and a common cathode 302. The n-contact material 316 and the common cathode 302 are in electrical contact with the n-type layer 304n by way of the current spreading layer 312. An anode 324 is in contact with the p-type layer 304p, and is positioned on a substrate 233.

An optical coating 305 is disposed on the current spreading layer 312, the optical coating 305 is opposite the n-type layer 304n and the first dielectric material 314. In one or more embodiments, the optical coating 305 comprises a second dielectric material. In one or more embodiments, the optical coating 305 is present in a configuration that is effective as an anti-reflective coating. In this embodiment, the optical layer 305 comprises a planar surface 305s opposite the current spreading layer 312.

FIG. 4 is a schematic view illustrating in cross-section a micro-light emitting diode (uLED) device including a die with uLEDs of FIG. 3 according to one or more embodiments. The uLED device 400 includes a uLED die 401 comprising a plurality of pixels each having a sidewall (analogously to FIG. 3) and each defined by a mesa 404, 406, 408, 410 of semiconductor layers, each the mesas 404, 406, 408, 410 including an n-type layer, an active region, and a p-type layer. A first dielectric material 414 surrounds the sidewall of each of the pixels. A plurality of n-contact materials 416, 418, 420 is positioned between adjacent pixels on the first dielectric material 414. A common electrode 402 is in electrical contact with the n-type layers and the n-contact materials 416, 418, 420. A plurality of anodes 424, 426, 428, 430, namely die anodes, are in contact with each of the p-type layers and corresponding contacts or electrodes (anodes) 434, 436, 438, 440 of a substrate 433. The common cathode 402 is in contact with corresponding contact or electrode (cathode) 442 of the substrate 433. In FIG. 4, upper edges of the mesas 404, 406, 408, 410 are off-set from upper edges of the n-contact materials 416, 418, 420 and common cathode 402. It is understood that other designs may planarize a combination of the upper edges of the mesas 404, 406, 408, 410 and the n-contact materials 416, 418, 420 and common cathode 402.

An optical coating 405 is disposed on the current spreading layer 412. The optical coating 305 is opposite the n-type layers of the mesas 404, 406, 408, and 410 and portions of the first dielectric material 414. In one or more embodiments, the optical layer 405 comprise a second dielectric material. In one or more embodiments, the optical coating is present in a configuration that is effective as an anti-reflective coating. In this embodiment, the optical coating 405 comprises a planar surface opposite the current spreading layer 412 The substrate 433 in one or more embodiments, is a target wafer to which die 401, as a source wafer, is bonded, for example, hybrid-bonded. In one or more embodiments, the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

According to one or more embodiments, for assembly of the uLED device, a process to achieve hybrid bonding is conducted. That is, the die 401 is hybrid-bonded to the substrate 433, which may be a target substrate having target metal contacts or electrodes. By way of example, a surface of each of the anodes 424, 426, 428, 430 is bonded to a surface of each corresponding contacts or electrodes (anodes) 434, 436, 438, 440 of the substrate 433. The common cathode 402 is bonded to contact or electrode (cathode) 442 of the substrate 433. In addition, first dielectric material 414 bonds to a body of the substrate 433, which in one or more embodiments, is a dielectric material.

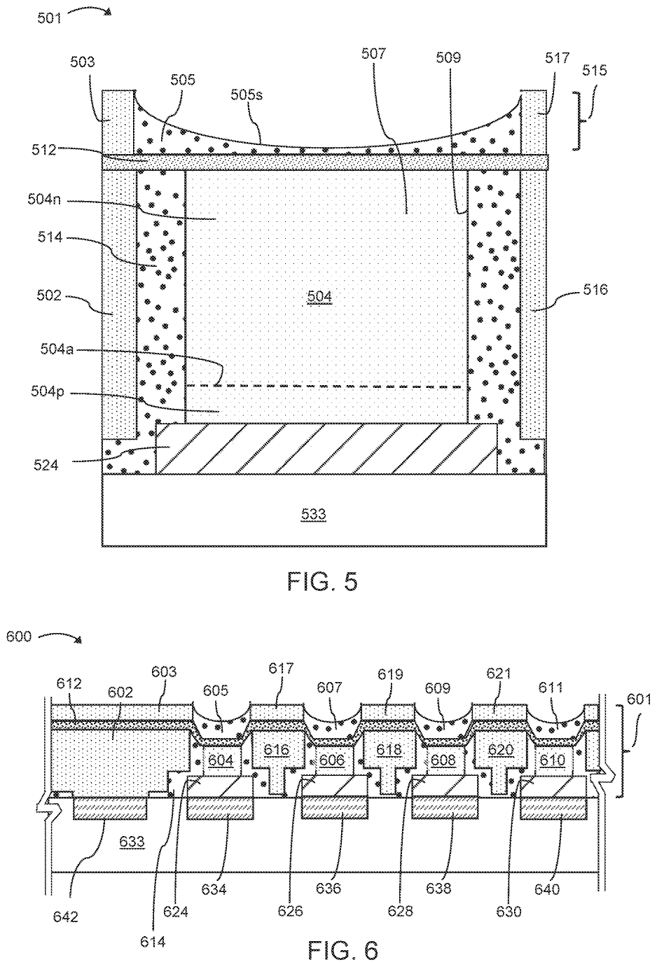

FIG. 5 is a schematic view illustrating in cross-section a micro-light emitting diode (uLED) according to one or more embodiments. The uLED 501 includes a pixel 507 defined by a mesa 504 of semiconductor layers having a sidewall 509, the mesa including an n-type layer 504n, an active region 504a, and a p-type layer 504p. A first dielectric material 514 surrounds the sidewall 509 of the pixel 507. A current spreading layer 512 is in contact with an n-contact material 516, the n-type layer 504n, a portion of the first dielectric material 514, and a common cathode 502. The n-contact material 516 and the common cathode 502 are in electrical contact with the n-type layer 504n by way of the current spreading layer 512. An anode 524 is in contact with the p-type layer 504p, and is positioned on a substrate 533.

An optical layer 515 is disposed on the current spreading layer 512, the optical layer 515 comprises: an optical segment 505 and a reflective sidewall 517 adjacent to the optical segment 505. The optical segment 505 is opposite the n-type layer 504n and the first dielectric material 514. In one or more embodiments, the optical segment 505 comprises a second dielectric material. The reflective sidewall 517 is opposite portions of the n-contact material 516 and the common cathode 505. In one or more embodiments, the optical layer 515 is present in a configuration that is effective as a lens for projected light of the pixel and/or an anti-reflective coating. In this embodiment, the optical segment 505 comprises a convex surface 505s opposite the current spreading layer 512. Reference to a convex surface herein means that such surface curves towards the current spreading layer, having its maximum thickness at its edges, nearest the reflective sidewall, and its minimum thickness therebetween, preferably at a center of the optical segment.

FIG. 6 is a schematic view illustrating in cross-section a micro-light emitting diode (uLED) device including a die with uLEDs of FIG. 5 according to one or more embodiments. The uLED device 600 includes a uLED die 601 comprising a plurality of pixels each having a sidewall (analogously to FIG. 5) and each defined by a mesa 604, 606, 608, 610 of semiconductor layers, each the mesas 604, 606, 608, 610 including an n-type layer, an active region, and a p-type layer. A first dielectric material 614 surrounds the sidewall of each of the pixels. A plurality of n-contact materials 616, 618, 620 is positioned between adjacent pixels on the first dielectric material 614. A common electrode 602 is in electrical contact with the n-type layers and the n-contact materials 616, 618, 620. A plurality of anodes 624, 626, 628, 630, namely die anodes, are in contact with each of the p-type layers and corresponding contacts or electrodes (anodes) 634, 636, 638, 640 of a substrate 633. The common cathode 602 is in contact with corresponding contact or electrode (cathode) 642 of the substrate 633. In FIG. 6, upper edges of the mesas 604, 606, 608, 610 are off-set from upper edges of the n-contact materials 616, 618, 620 and common cathode 602. It is understood that other designs may planarize a combination of the upper edges of the mesas 604, 606, 608, 610 and the n-contact materials 616, 618, 620 and common cathode 602.

An optical layer comprising: optical segments 605, 607, 609, and 611, and reflective sidewalls 603, 617, 619, 611 adjacent to the optical segments 605 is disposed on the current spreading layer 612. The optical segments 605, 607, 609, and 611 are opposite the n-type layers of the mesas 604, 606, 608, and 610 and portions of the first dielectric material 614. In one or more embodiments, the optical segments 605, 607, 609, and 611 comprise a second dielectric material. The reflective sidewalls 617, 619, 611 are opposite portions of the n-contact materials 616, 618, and 620. The reflective sidewall 603 is opposite the common cathode 602. In one or more embodiments, the optical layer is present in a configuration that is effective as a lens for projected light of the pixel and/or an anti-reflective coating. In this embodiment, the optical segments 605, 607, 609, and 611 comprise a convex surface opposite the current spreading layer 612

The substrate 633 in one or more embodiments, is a target wafer to which die 601, as a source wafer, is bonded, for example, hybrid-bonded. In one or more embodiments, the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

According to one or more embodiments, for assembly of the uLED device, a process to achieve hybrid bonding is conducted. That is, the die 601 is hybrid-bonded to the substrate 633, which may be a target substrate having target metal contacts or electrodes. By way of example, a surface of each of the anodes 624, 626, 628, 630 is bonded to a surface of each corresponding contacts or electrodes (anodes) 634, 636, 638, 640 of the substrate 633. The common cathode 602 is bonded to contact or electrode (cathode) 642 of the substrate 633. In addition, first dielectric material 614 bonds to a body of the substrate 633, which in one or more embodiments, is a dielectric material.

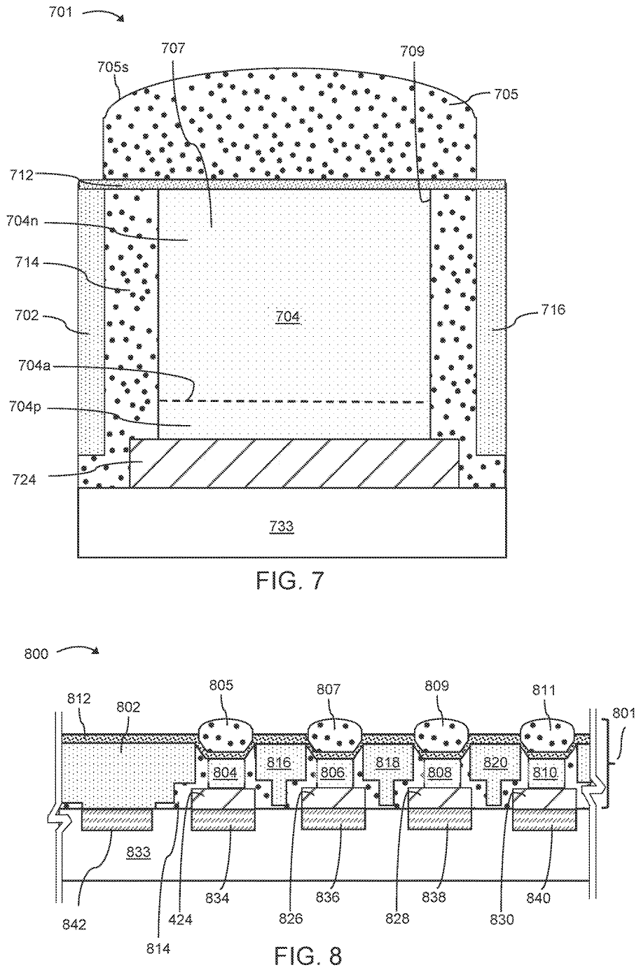

FIG. 7 is a schematic view illustrating in cross-section a micro-light emitting diode (uLED) according to one or more embodiments. The uLED 701 includes a pixel 707 defined by a mesa 704 of semiconductor layers having a sidewall 709, the mesa including an n-type layer 704n, an active region 704a, and a p-type layer 704p. A first dielectric material 714 surrounds the sidewall 709 of the pixel 707. A current spreading layer 712 is in contact with an n-contact material 716, the n-type layer 704n, a portion of the first dielectric material 714, and a common cathode 702. The n-contact material 716 and the common cathode 702 are in electrical contact with the n-type layer 704n by way of the current spreading layer 712. An anode 724 is in contact with the p-type layer 704p, and is positioned on a substrate 733.

An optical coating that has been patterned into optical segment 705 is disposed on the current spreading layer 712. This embodiment does not include reflective sidewalls. The optical segment 705 is opposite the n-type layer 704n and the first dielectric material 714. In one or more embodiments, the optical segment 705 comprises a second dielectric material. In one or more embodiments, the optical segment 705 is present in a configuration that is effective as an anti-reflective coating. In this embodiment, the optical segment 705 comprises a concave surface 705s opposite the current spreading layer 712. Reference to a concave surface herein means that such surface curves away from the current spreading layer, having its minimum thickness at outer edges and its minimum thickness therebetween, preferably at a center of the optical segment.

FIG. 8 is a schematic view illustrating in cross-section a micro-light emitting diode (uLED) device including a die with uLEDs of FIG. 7 according to one or more embodiments. The uLED device 800 includes a uLED die 801 comprising a plurality of pixels each having a sidewall (analogously to FIG. 7) and each defined by a mesa 804, 806, 808, 810 of semiconductor layers, each the mesas 804, 806, 808, 810 including an n-type layer, an active region, and a p-type layer. A first dielectric material 814 surrounds the sidewall of each of the pixels. A plurality of n-contact materials 816, 818, 820 is positioned between adjacent pixels on the first dielectric material 814. A common electrode 802 is in electrical contact with the n-type layers and the n-contact materials 816, 818, 820. A plurality of anodes 824, 826, 828, 830, namely die anodes, are in contact with each of the p-type layers and corresponding contacts or electrodes (anodes) 834, 836, 838, 840 of a substrate 833. The common cathode 802 is in contact with corresponding contact or electrode (cathode) 842 of the substrate 833. In FIG. 8, upper edges of the mesas 804, 806, 808, 810 are off-set from upper edges of the n-SUBSTITUTE contact materials 816, 818, 820 and common cathode 802. It is understood that other designs may planarize a combination of the upper edges of the mesas 804, 806, 808, 810 and the n-contact materials 816, 818, 820 and common cathode 802.

An optical coating that has been patterned to form optical segments 805, 807, 809, and 811 is disposed on the current spreading layer 812. The optical segments 805, 807, 809, and 811 are opposite the n-type layers of the mesas 804, 806, 808, and 810 and portions of the first dielectric material 814. In one or more embodiments, the optical segments 805, 807, 809, and 811 comprise a second dielectric material. In one or more embodiments, the optical segments are present in a configuration that is effective as a lens for projected light of the pixel and/or an anti-reflective coating. In this embodiment, the optical segments 805, 807, 809, and 811 comprise a concave surface opposite the current spreading layer 812

The substrate 833 in one or more embodiments, is a target wafer to which die 801, as a source wafer, is bonded, for example, hybrid-bonded. In one or more embodiments, the target wafer is a complementary metal-oxide semiconductor (CMOS) wafer that is hybrid-bonded to the source wafer in that there is a combination of a metal-to-metal bonds and dielectric-to-dielectric bonds between the source wafer and the target wafer.

According to one or more embodiments, for assembly of the uLED device, a process to achieve hybrid bonding is conducted. That is, the die 801 is hybrid-bonded to the substrate 833, which may be a target substrate having target metal contacts or electrodes. By way of example, a surface of each of the anodes 824, 826, 828, 830 is bonded to a surface of each corresponding contacts or electrodes (anodes) 834, 836, 838, 840 of the substrate 833. The common cathode 802 is bonded to contact or electrode (cathode) 842 of the substrate 833. In addition, first dielectric material 814 bonds to a body of the substrate 833, which in one or more embodiments, is a dielectric material.

In one or more embodiments herein, the first and second dielectric material independently comprise one or more of: silicon oxide (SiO), silicon dioxide (SiO2), silicon nitride (SiN), silicon carbide (SiC), aluminum oxide (A1203), and aluminum nitride (AIN).

In one or more embodiments herein, the common cathode, the anodes, the n-contacts, and the reflective sidewalls comprise one or more of: copper (Cu), aluminum (Al), nickel (Ni), titanium (Ti), titanium-tungsten (TiW), silver (Ag), gold (Au), platinum (Pt), and palladium (Pd).

In one or more embodiments herein, the current spreading layer comprises indium tin oxide (ITO) and/or indium zinc oxide (IZO).

In one or more embodiments herein, the n-type layer comprises n-GaN and the p-type layer comprises p-GaN.

In one or more embodiments herein, a thickness of n-type layer is in a range of from 0.05 μm to 0.5 μm, and all values and ranges therebetween, and/or a thickness of p-type layer is in a range of from 0.05 μm to 0.5 μm, and all values and ranges therebetween.

In one or more embodiments, the target metal contacts comprise one or more of: copper (Cu), aluminum (Al), nickel (Ni), titanium (Ti), titanium-tungsten (TiW), silver (Ag), gold (Au), platinum (Pt), and palladium (Pd).

In one or more embodiments, the target wafer comprises a substrate material selected from the group consisting of: ceramic, silicon, aluminum, a sapphire, silicon carbide, and III-nitride. In one or more embodiments, a substrate body comprises a dielectric material selected from the group consisting of: silicon oxide (SiO), silicon dioxide (SiO2), silicon nitride (SiN), silicon carbide (SiC), aluminum oxide (Al2O3), and aluminum nitride (AIN).

In one or more embodiments, the target substrate further comprises a material selected from the group consisting of: ceramic, silicon, aluminum, sapphire, silicon carbide, and III-nitride.

In one or more embodiments, die anodes are directly bonded to corresponding target wafer electrodes over respective p-contact bond areas, and wherein diameters of the p-contact bond areas have a diameter in a range of 0.5 micrometers to less than or equal to 30 micrometers, including all values and subranges therebetween. In one or more embodiments, a width of each of the die anodes is 95% to 100%, and all values and subranges therebetween of a width of each of the corresponding target wafer electrodes at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

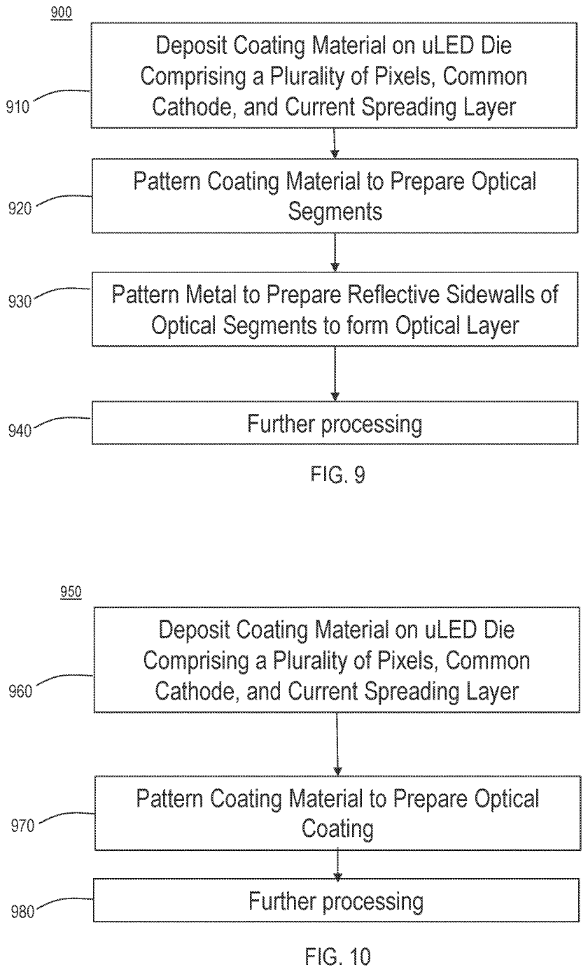

FIG. 9 provides a process flow diagram for manufacture of a micro-light emitting diode (uLED) die according to one or more embodiments. Manufacturing process 900 includes a first operation at 910 where a coating material is deposited on a uLED die having a plurality of pixels, a common cathode, and a current spreading layer. At operation 920, the coating material is patterned, for example by etching preferably selective etching, to prepare optical segments. At operation 930, metal is deposited and patterned, for example by etching, to prepare reflective sidewalls of the optical segments, thereby forming an optical layer.

In one or more embodiments, the patterning is according to any appropriate technique known to one of skill in the art. According to one or more embodiments, conventional masking, wet etching and/or dry etching processes can be used to for patterning.

At operation 940, the uLED dies are further processed to be bonded to a substrate, e.g., a target wafer.

FIG. 10 provides a process flow diagram for manufacture of a micro-light emitting diode (uLED) die according to one or more embodiments. Manufacturing process 950 includes a first operation at 960 where a coating material is deposited on a uLED die having a plurality of pixels, a common cathode, and a current spreading layer. At operation 970, the coating material is patterned, for example by etching preferably selective etching, to prepare an optical coating.

In one or more embodiments, the patterning is according to any appropriate technique known to one of skill in the art. According to one or more embodiments, conventional masking, wet etching and/or dry etching processes can be used to for patterning.

At operation 980, the uLED dies are further processed to be bonded to a substrate, e.g., a target wafer.

### uLED Devices

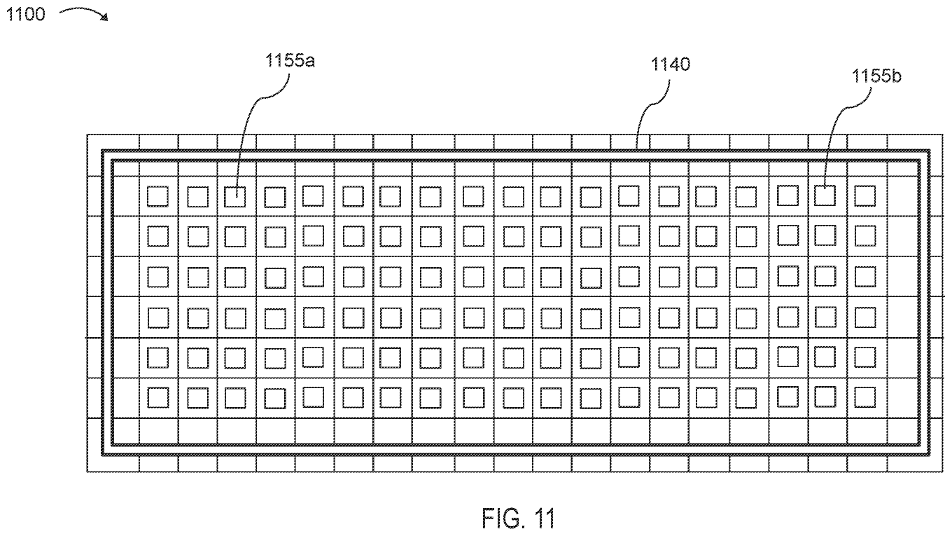

FIG. 11 shows a top plan view of an exemplary uLED display device comprising a uLED monolithic array 1100 comprising a plurality of pixels arranged in a grid of 6×19. Pixels 1155a and 1155b are examples. In this embodiment, a common cathode 1140 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of micro-LEDs (uLEDs or uLEDs) are used. Micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths.

In some embodiments, the light emitting arrays include small numbers of micro-LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, micro-LEDs can include light emitting diodes sized between 30 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

In some embodiments, LED light emitting arrays include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### Applications

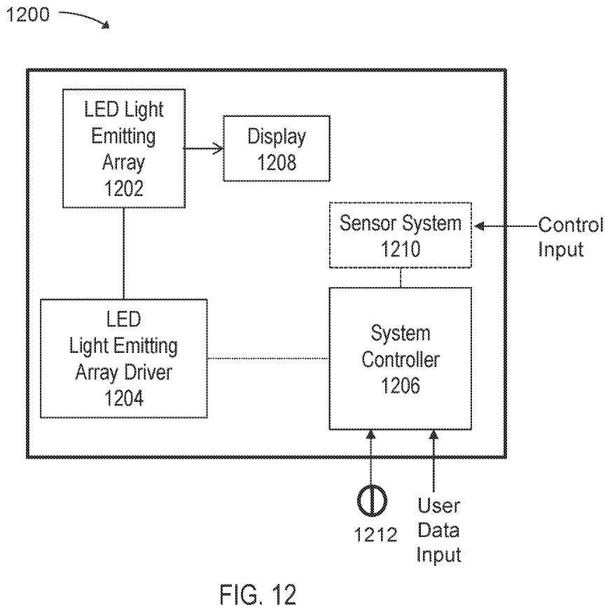

FIG. 12 schematically illustrates an exemplary display system 1200 utilizing LEDs, including uLEDs, disclosed herein. The display system 1200 comprises an LED light emitting array 1202 and display 1208 in electrical communication with an LED driver 1204. The display system 1200 also comprises a system controller 1206, such as a microprocessor. The controller 1206 is coupled to the LED driver 1204. The controller 1206 may also be coupled to the display 1208 and to optional sensor(s) 1210, and be powered by power source 1212. In one or more embodiments, user data input is provided to system controller 1206.

In one or more embodiments, the system is a camera flash system utilizing uLEDs. In such an embodiment, the LED light emitting array 1202 is an illumination array and lens system and the display 1208 comprises a camera, wherein the LEDs of 1202 and the camera of 1208 may be controlled by the controller 1206 to match their fields of view.

Optionally sensors 1210 with control input may include, for example, positional sensors (e.g., a gyroscope and/or accelerometer) and/or other sensors that may be used to determine the position, speed, and orientation of system. The signals from the sensors 1210 may be supplied to the controller 1206 to be used to determine the appropriate course of action of the controller 1206 (e.g., which LEDs are currently illuminating a target and which LEDs will be illuminating the target a predetermined amount of time later).

In operation, illumination from some or all of the pixels of the LED array in 1202 may be adjusted-deactivated, operated at full intensity, or operated at an intermediate intensity. As noted above, beam focus or steering of light emitted by the LED array in 1202 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

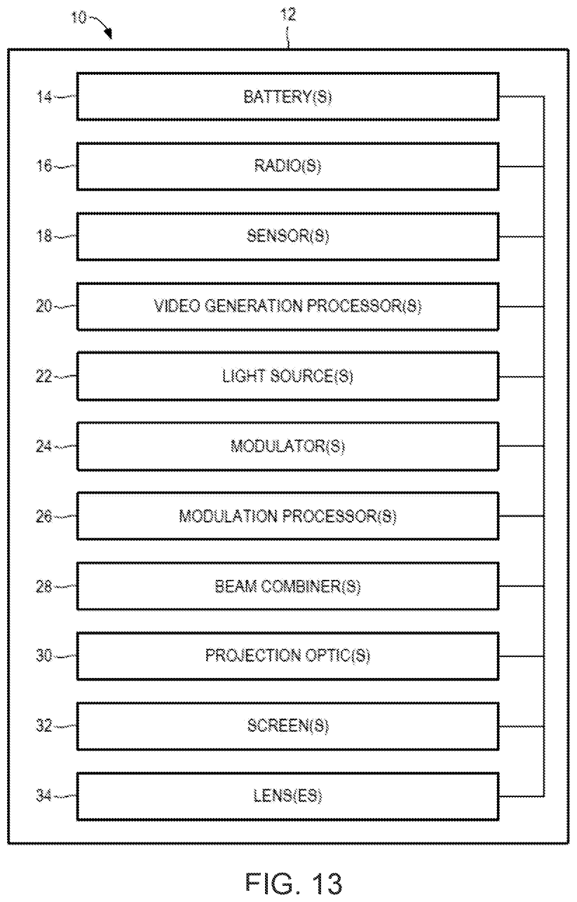

FIG. 13 shows a block diagram of an example of a visualization system 10. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive, from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

### Embodiments

Various embodiments are listed below. It will be understood that the embodiments listed below may be combined with all aspects and other embodiments in accordance with the scope of the invention.

Embodiment (a) A micro-light emitting diode (uLED) comprising: a pixel defined by a mesa of semiconductor layers having a sidewall, the mesa including an n-type layer, an active region, and a p-type layer; a first dielectric material surrounding the sidewall of the pixel; a current spreading layer in contact with one or more n-contact materials and the n-type layer; an optical layer disposed on the current spreading layer, the optical layer comprising: an optical segment opposite the n-type layer and the first dielectric material, the optical segment comprising a second dielectric material, and a reflective sidewall adjacent to the optical segment and opposite portions of the one or more n-contact materials; and an anode in contact with the p-type layer.

Embodiment (b) The uLED of embodiment (a), wherein the optical segment is centered on the pixel.

Embodiment (c) The uLED of embodiment (a) or (b), wherein the optical segment comprises a planar surface opposite the current spreading layer.

Embodiment (d) The uLED of embodiment (a) or (b), wherein the optical segment comprises a concave surface opposite the current spreading layer.

Embodiment (e) The uLED of any of embodiments (a) to (d), wherein the first and second dielectric material independently comprise one or more of: silicon oxide (SiO), silicon dioxide (SiO₂), silicon nitride (SiN), silicon carbide (SiC), aluminum oxide (Al₂O₃), and aluminum nitride (AIN); and/or the anode, and the n-contact materials, and the reflective sidewall comprises one or more of: copper (Cu), aluminum (Al), nickel (Ni), titanium (Ti), titanium-tungsten (TiW), silver (Ag), gold (Au), platinum (Pt), and palladium (Pd).

Embodiment (f) The uLED of any of embodiments (a) to (e), wherein the optical segment comprises a minimal thickness in a range of 500 nanometers to 1 micrometer.

Embodiment (g) The uLED of any of embodiments (a) to (f), wherein the optical segment comprises a layered structure.

Embodiment (h) The uLED of embodiment (g), wherein the layered structure comprises one or more pairs of silicon dioxide (SiO₂) and titanium dioxide (TiO₂) layers, or of silicon dioxide (SiO₂) and niobium pentoxide (NbO₅) layers.

Embodiment (i) The uLED of any of embodiments (a) to (h), wherein upon application of power to the pixel, a far-field angular emission response for an angle (θ) of greater than or equal to 0° to less than or equal to 40° is higher than a comparative uLED without the optical layer and otherwise having a same structure.

Embodiment (j) A micro-light emitting diode (uLED) die comprising: a plurality of pixels each having a sidewall and being defined by a mesa of semiconductor layers, each the mesas including an n-type layer, an active region, and a p-type layer; a first dielectric material surrounding the sidewall of each of the pixels; a plurality of n-contact materials between adjacent pixels on the first dielectric material; a current spreading layer in contact with a common cathode each of the n-type layers, and the n-contact materials; an optical layer on the current spreading layer, the optical layer comprising: an optical segment opposite each of the n-type layers and the first dielectric material, the optical segment comprising a second dielectric material, and a reflective sidewall adjacent to the optical segment and opposite portions of the n-contact materials; and a plurality of anodes in contact with each of the p-type layers.

Embodiment (k) The uLED die of embodiment (j), wherein the optical segment comprises a planar surface opposite the current spreading layer.

Embodiment (l) The uLED die of embodiment (j) or (k), wherein the optical segment comprises a concave surface opposite the current spreading layer.

Embodiment (m) The uLED die of any of embodiments (j) to (l), wherein the optical segment comprises a minimal thickness in a range of 500 nanometers to 1 micrometer.

Embodiment (n) The uLED die of any of embodiments (j) to (m), wherein the optical segment comprises a layered structure.

Embodiment (o) The uLED die of embodiment (n), wherein the layered structure comprises one or more pairs of silicon dioxide (SiO₂) and titanium dioxide (TiO₂) layers, or of silicon dioxide (SiO₂) and niobium pentoxide (NbO₅) layers.

Embodiment (p) The uLED die of any of embodiments (j) to (o), wherein the optical segment is centered on each of the pixels.

Embodiment (q) The uLED die of any of embodiments (j) to (p), wherein the first and second dielectric material independently comprise one or more of: silicon oxide (SiO), silicon dioxide (SiO₂), silicon nitride (SiN), silicon carbide (SiC), aluminum oxide (Al₂O₃), and aluminum nitride (AIN); and/or the anodes, and the n-contact materials, and the reflective sidewall comprises one or more of: copper (Cu), aluminum (Al), nickel (Ni), titanium (Ti), titanium-tungsten (TiW), silver (Ag), gold (Au), platinum (Pt), and palladium (Pd).

Embodiment (r) The uLED die of any of embodiments (j) to (q), wherein the current spreading layer comprises indium tin oxide (ITO) and/or indium zinc oxide (IZO).

Embodiment(s) A micro-light emitting diode (uLED) device comprising: a source wafer comprising the micro-light emitting diode (uLED) die of any of embodiments (j) to (r); and a target wafer bonded to the source wafer.

Embodiment (t) The uLED device of embodiment(s), wherein the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

Embodiment (u) The uLED device of embodiment(s) or (t), wherein the target wafer comprises a substrate material selected from the group consisting of: ceramic, silicon, aluminum, a sapphire, silicon carbide, and III-nitride.

Embodiment (v) Any uLED or uLED die or uLED device of embodiments (a) to (u), wherein a thickness of the mesa is in a range of from 1 μm to 10 μm.

Embodiment (w) Any uLED or uLED die or uLED device of embodiments (a) to (v), wherein the n-type layer and the p-type layer each comprise GaN.

Embodiment (ww) Any uLED or uLED die or uLED device of embodiments (a) to (w), wherein the optical layer is present in a configuration that is effective as a lens for projected light of each of the pixels.

Embodiment (xx) Any uLED or uLED die or uLED device of embodiments (a) to (w), wherein the optical layer is present in a configuration that is effective as an anti-reflective coating.

Embodiment (y) A method of manufacturing a micro-light emitting diode (uLED) device comprising: depositing a coating material on a micro-light emitting diode (uLED) die comprising: a plurality of pixels that comprises a mesa of semiconductor layers, a first dielectric material surrounding a sidewall of each of the pixels, and a current spreading layer connecting a common cathode and each n-type layer of the mesas; selectively etching the coating material to prepare optical segments on the current spreading layer opposite each of the n-type layers and the first dielectric material the optical segments comprising a second dielectric material; and depositing and etching a metal material to prepare reflective sidewalls of the optical segments to form an optical layer comprising the optical segments and the reflective sidewalls.

Embodiment (yy) The method of embodiment (y), wherein the semiconductor layers are deposited on a growth substrate which is removed prior to a depositing of the current spreading layer onto the n-type layer.

Embodiment (z) The method of embodiment (x) or (y) or (yy), wherein the optical layer is present in a configuration that is effective as a lens for projected light of each of the pixels and/or as an anti-reflective coating.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A micro-light emitting diode (uLED) comprising:
a pixel defined by a mesa of semiconductor layers having a sidewall, the mesa including an n-type layer, an active region, and a p-type layer;
a first dielectric material surrounding the sidewall of the pixel;
a current spreading layer in contact with one or more n-contact materials and the n-type layer;
an optical layer disposed on the current spreading layer, the optical layer comprising: an optical segment opposite the n-type layer and the first dielectric material, the optical segment comprising a second dielectric material, and a reflective sidewall adjacent to the optical segment and opposite portions of the one or more n-contact materials; and
an anode in contact with the p-type layer.

2. The uLED of claim 1, wherein the optical segment is centered on the pixel.

3. The uLED of claim 1, wherein the optical segment comprises a planar surface opposite the current spreading layer.

4. The uLED of claim 1, wherein the optical segment comprises a concave surface opposite the current spreading layer.

5. The uLED of claim 1, wherein the first and second dielectric material independently comprise one or more of: silicon oxide (SiO), silicon dioxide (SiO₂), silicon nitride (SIN), silicon carbide (SIC), aluminum oxide (Al₂O₃), and aluminum nitride (AIN); and/or the anode, and the n-contact materials, and the reflective sidewall comprises one or more of: copper (Cu), aluminum (Al), nickel (Ni), titanium (Ti), titanium-tungsten (TiW), silver (Ag), gold (Au), platinum (Pt), and palladium (Pd).

6. The uLED of claim 1, wherein the optical segment comprises a minimal thickness in a range of 500 nanometers to 1 micrometer.

7. The uLED of claim 1, wherein the optical segment comprises a layered structure.

8. The uLED of claim 7, wherein the layered structure comprises one or more pairs of silicon dioxide (SiO₂) and titanium dioxide (TiO₂) layers, or of silicon dioxide (SiO₂) and niobium pentoxide (NbO₅) layers.

9. A micro-light emitting diode (uLED) die comprising:
a plurality of pixels each having a sidewall and being defined by a mesa of semiconductor layers, each the mesas including an n-type layer, an active region, and a p-type layer;
a first dielectric material surrounding the sidewall of each of the pixels;
a plurality of n-contact materials between adjacent pixels on the first dielectric material;
a current spreading layer in contact with a common cathode each of the n-type layers, and the n-contact materials;
an optical layer on the current spreading layer, the optical layer comprising: an optical segment opposite each of the n-type layers and the first dielectric material, the optical segment comprising a second dielectric material, and a reflective sidewall adjacent to the optical segment and opposite portions of the n-contact materials; and
a plurality of anodes in contact with each of the p-type layers.

10. The uLED die of claim 9, wherein the optical segment comprises a planar surface opposite the current spreading layer.

11. The uLED die of claim 9, wherein the optical segment comprises a concave surface opposite the current spreading layer.

12. The uLED die of claim 9, wherein the optical segment comprises a minimal thickness in a range of 500 nanometers to 1 micrometer.

13. The uLED die of claim 9, wherein the optical segment comprises a layered structure.

14. The uLED die of claim 13, wherein the layered structure comprises one or more pairs of silicon dioxide (SiO₂) and titanium dioxide (TiO₂) layers, or of silicon dioxide (SiO₂) and niobium pentoxide (NbO₅) layers.

15. The uLED die of claim 9, wherein the current spreading layer comprises indium tin oxide (ITO) and/or indium zinc oxide (IZO).

16. A micro-light emitting diode (uLED) device comprising:
a source wafer comprising the micro-light emitting diode (uLED) die of claim 10; and
a target wafer bonded to the source wafer.

17. The uLED device of claim 16, wherein the target wafer is a complementary metal-oxide-semiconductor (CMOS) wafer that is hybrid-bonded to the source wafer in that there is a combination of a metal-to-metal bonds and dielectric-to-dielectric bonds between the source wafer and the target wafer.

18. The uLED device of claim 16, wherein the target wafer comprises a substrate material selected from the group consisting of: ceramic, silicon, aluminum, a sapphire, silicon carbide, and III-nitride.

19. A method of manufacturing the micro-light emitting diode (uLED) device of claim 9, the method comprising:
depositing a coating material on a micro-light emitting diode (uLED) die comprising: the plurality of pixels that comprises the mesa of semiconductor layers, the first dielectric material surrounding the sidewall of each of the pixels, and the current spreading layer connecting the common cathode and each n-type layer of the mesas;
selectively etching the coating material to prepare optical segments on the current spreading layer opposite each of the n-type layers and the first dielectric material the optical segments comprising a second dielectric material;
depositing and etching a metal material to prepare reflective sidewalls of the optical segments to form an optical layer comprising the optical segments and the reflective sidewalls.

20. The method of claim 19, wherein the semiconductor layers are deposited on a growth substrate which is removed prior to a depositing of the current spreading layer onto the n-type layer.
